(19) United States
(12) Patent Application Publication
(10) Pub. No.: US 2016/0064252 A1
(43) Pub. Date: Mar. 3, 2016

(54) ELECTRONIC MODULE HAVING AN OXIDE SURFACE FINISH AS A SOLDER MASK, AND METHOD OF MANUFACTURING ELECTRONIC MODULE USING ORGANIC SOLDERABILITY PRESERVATIVE AND OXIDE SURFACE FINISH PROCESSES

(71) Applicant: Avago Technologies General IP (Singapore) Pte. Ltd., Singapore (SG)

(72) Inventor: Jack Ajoian, Campbell, CA (US)

(21) Appl. No.: 14/471,733

(22) Filed: Aug. 28, 2014

(51) Int. Cl. H01L 21/48; H01L 21/56; H01L 23/495

(52) U.S. Cl. CPC H01L 21/4828; H01L 23/49575; H01L 23/49524; H01L 23/49582; H01L 23/49586; H01L 21/565; H01L 21/481; H01L 2021/60015

(57) ABSTRACT

An electronic module includes a substrate, conductive pads at top and bottom surfaces of the substrate, at least one electronic component disposed on the top surface of the substrate and soldered to the pads at the top surface of the substrate, a molding compound covering the at least one electronic component, and a solder resist comprising an organo-metallic compound at regions between respective ones of the pads at the bottom surface of the substrate. The module is manufactured using both an OSP surface finishing process to coat the pads at the top surface of the substrate with OSP so as to protect the pads from oxidation while the electronic component is being connected to the substrate, and an oxide surface finish process to form the solder resist.

### TECHNICAL FIELD

The present inventive concept relates to electronic modules that include at least one electronic component and associated electrical interconnections and which can be linked with a larger unit such as a printed circuit board (PCB). The present inventive concept also relates to methods of manufacturing such modules. In particular, the inventive concept relates to electronic modules including a substrate having conductive pads at its top and bottom, and at least one die or chip mounted on and electrically connected to the substrate, and to methods of manufacturing the same.

### BACKGROUND

Various electronic products include a main printed circuit board (PCB) such as a motherboard, and an electronic module(s) mounted to the PCB. The electronic module includes one or more integrated circuits (ICs) to be connected to the main printed circuit board, and employs any of various types of packaging technologies for the integrated circuits (ICs). Examples of these packaging technologies include land grid array (LGA) and ball grid array (BGA) packaging technologies.

A conventional LGA package includes a substrate, arrays of conductive pads at the top and bottom of the substrate, respectively, and a chip or die disposed on the substrate and electrically connected to respective ones of the pads at the top of the substrate. A conventional BGA package is similar to the LGA package but additionally includes balls of solder held by flux on the pads at the bottom of the substrate. In either case, the chip or die is often embedded in and hence, protected, by a compound molded to the substrate. The packages also have conductive vias, such as through vias extending through the substrate and electrically connecting pads at the top of the substrate with pads at the bottom of the substrate. Thvias provide an electrical connection of the chip or die to the pads at the bottom of the substrate.

Such a conventional LGA package may be surface mounted to a PCB. Specifically, a grid of solder paste corresponding to the pads at the bottom of the substrate of the LGA package may be formed on the PCB, the LGA package is set on the PCB with its pads disposed on the pads of solder paste, and a reflow process is carried out such that the LGA package is soldered directly to the PCB. Likewise, a conventional BGA package may be surface mounted to a PCB. Specifically, the solder balls may be placed on corresponding copper (Cu) pads of the PCB, and a reflow process is carried out on the solder balls such that the BGA package is soldered directly to the PCB.

### SUMMARY

One object is to provide an electronic module that will remain highly reliable when surface mounted to another electronic product such as a PCB.

Another object is to provide an electronic module that has conductive lands at the bottom thereof and which can reliably prevent solder from bridging adjacent ones of the lands when the lands are soldered to contacts of another electronic product such as a PCB.

According to one aspect of the inventive teachings, there is provided method of manufacturing an electronic module, which includes providing a base including a substrate and conductive pads at each of top and bottom surfaces of the substrate, coating the pads at the top surface of the substrate with organic solderablity preservative (OSP), disposing at least one electronic component on the base and electrically connecting the at least one electronic component to respective ones of the pads at the top of the substrate of the base, covering the at least one electronic component with a molding compound, and carrying out an oxidation process to form a solder resist at regions between the respective ones of the pads at the bottom surface of the substrate.

According to another aspect of the inventive teachings, there is provided method of manufacturing an electronic module, which includes providing a base including a substrate and exposed copper pads at top surface of the substrate and an array of conductive lands at the bottom surface of the substrate, a metal surface finishing process comprising coating the exposed Cu pads at the top surface of the substrate with organic solderability preservative (OSP), disposing at least one electronic component on the top surface of the substrate and soldering the at least one electronic component to the pads at the top surface of the substrate, covering the at least one electronic component with a molding compound, and producing a solder resist comprising an organo-metallic compound at the exposed surface of regions between respective ones of the lands at the bottom surface of the substrate. A conductive layer constitutes the array of conductive lands at the bottom surface of the substrate. The conductive layer includes a film of copper (Cu), and has a first relatively thick portion constituting the array of conductive lands and a second thinner portion of exposed regions of the film of Cu. The exposed regions of the film of Cu extend between respective ones of the lands at the bottom surface of the substrate.

According to still another aspect of the inventive teachings, there is provided an electronic module, which includes a substrate, conductive pads at each of top and bottom surfaces of the substrate, at least one electronic component disposed on the top surface of the substrate and electrically connected to the pads at the top surface of the substrate, a molding compound covering the at least one electronic compound, and a solder resist comprising an organo-metallic compound at regions between respective ones of the pads at the bottom surface of the substrate.

### BRIEF DESCRIPTION OF THE DRAWINGS

These and other objects, features and advantages in accordance with the inventive concept will be better understood from the detailed description of the preferred embodiments that follows with reference to the accompanying drawings, in which:

FIG. 1 is a process flow diagram of a method of manufacturing an electronic module according to the present inventive concept;

FIG. 2 is a cross-sectional view of an example of a substrate having conductive layers, and illustrates a process of etching the layers to prepare the substrate for a method of manufacturing an electronic module according to the present inventive concept;

FIG. 3 is a cross-sectional view and illustrates an example of the OSP surface finish process of FIG. 1 as carried out on a substrate in a method of manufacturing an electronic module according to the present inventive concept;

FIG. 4 is a cross-sectional view of the product formed after the OSP surface finish process has been completed and illustrates an example of the assembly process of FIG. 1 in the method of manufacturing an electronic module according to the present inventive concept;

FIG. 5 is a cross-sectional view of the product formed after the assembly process has been completed and illustrates an example of the overmold process of FIG. 1 in the method of manufacturing an electronic module according to the present inventive concept;

FIG. 6 is a cross-sectional view of one embodiment of an electronic module according to the present inventive concept and illustrates an example of the oxide surface finish process of FIG. 1;

FIG. 7A is a bottom view of a product formed after the OSP surface finish process has been completed; and

FIG. 7B is a bottom view of an electronic module according to the present inventive concept.

### DETAILED DESCRIPTION OF THE PREFERRED EMBODIMENTS

Various embodiments and examples of embodiments of the present inventive concept will be described more fully hereinafter with reference to the accompanying drawings. In the drawings, the sizes and relative sizes and shapes of elements, layers and regions shown in section may be exaggerated for clarity. In particular, the cross-sectional illustration of the module and intermediate structures fabricated during the course of its manufacture are schematic. Also, like numerals are used to designate like elements throughout the drawings.

As used in the specification and appended claims, the terms “a”, “an” and “the” include both singular and plural referents, unless the context clearly dictates otherwise. Thus, for example, “a device” includes one device and plural devices. As used in the specification and appended claims for the purpose of describing particular examples or embodiments of the inventive concept is to be taken in context. For example, the terms “comprises” or “comprising” when used in this specification and appended claims specifies the presence of stated features, materials or processes but does not preclude the presence or additional features, materials or processes. As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” or “about” means to within an acceptable limit or amount to one having ordinary skill in the art. For example, “approximately the same” means that one of ordinary skill in the art would consider the items being compared to be the same. Furthermore, spatially relative terms, such as “upper” and “lower” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the present inventive concept can assume orientations different than those illustrated in the drawings when in use.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present.

Other terminology used herein for the purpose of describing particular examples or embodiments of the inventive concept is to be taken in context. For example, the terms “comprises” or “comprising” when used in this specification specifies the presence of stated features, materials or processes but does not preclude the presence or additional features, materials or processes. The terms “pads” and “lands” will be used synonymously to refer to features that are raised relative to some surface.

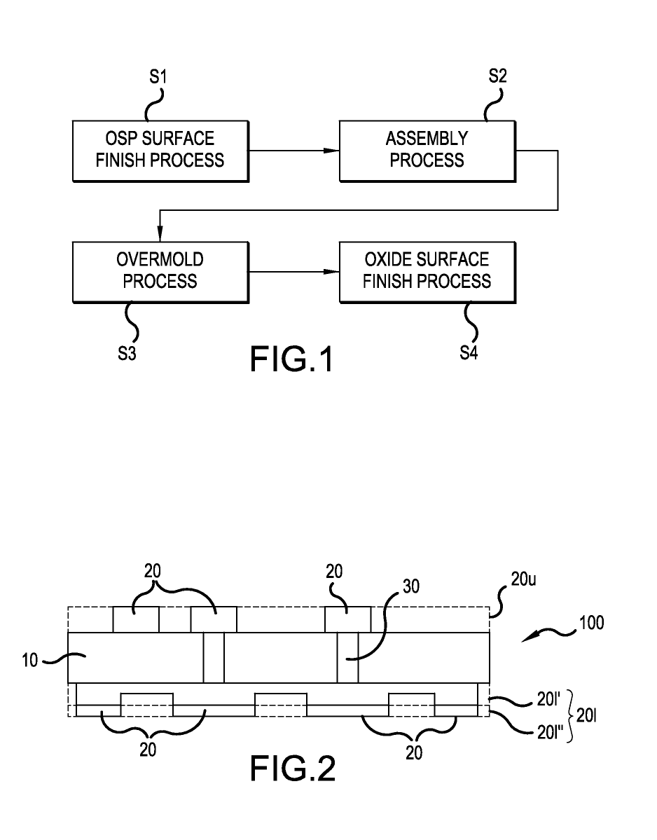

A method of manufacturing an electronic module according to the present inventive concept will now be described in detail with reference to FIGS. 1-7.

Referring first to FIG. 1, the method may be divided into an OSP surface finish process S1 which includes coating conductive pads of a base of the module with an organic solder preservative (OSP), followed by an assembly process S2 which includes soldering at least one electronic component to respective ones of the conductive pads at one side of the base, followed by an overmold process S3 which includes forming a molding compound over the electronic component(s) to cover the same on the base of the module, followed by an oxide surface finish process which includes forming an organo-metallic compound as a solder resist between the conductive pads at the other side of the base.

FIG. 2 shows an example of a base 100 of the electronic module that may be processed as described above. The base 100 includes a substrate 10, and conductive pads 20 (i.e., lands of conductive material) at each of top and bottom surfaces of the substrate 10. The base 100 may also include conductive vias 30 that connect respective ones of the conductive pads 20 at the top surface of the substrate 10 to respective ones of the conductive pads 20 at the bottom surface of the substrate 10. As shown in the figure, the substrate 10 may have only a single layer of electrically insulating material and the vias 30 may be through-vias that extend vertically through the substrate 10. Moreover, a dielectric layer may be provided on the bottom surface of the layer of insulating material.

Alternatively, the substrate 10 could be a multi-layered substrate of alternating layers of insulating material and wiring layers, and vias each extending through one or more of the layers of insulating material. That is, each via may be through-via connecting a pad at the top surface of the substrate to a pad at the bottom surface of the substrate, a blind via connecting a pad at one of the top and bottom surfaces of the substrate to a wiring layer within the substrate, or a buried via connecting respective ones of the wiring layers to each other within the substrate. In this case, a dielectric layer may be provided at the bottom of the substrate, i.e., on the bottom surface of the lowermost one of the layers of insulating material.

Still further, the base 100 may include one or more internal ICs (not shown) provided within the substrate 10 as disposed on a surface of one of the insulating layers and connected to a wiring layer on the same surface.

FIG. 2 also shows an example of how the base 100 is prepared. An upper conductive layer 20u is formed on the top surface of the substrate 10, and a lower conductive layer 20l is formed on the bottom surface of the substrate 10, as shown by the dashed lines in the figure. The lower conductive layer 20l may be formed by forming a primary metallic film 20l ′ on the bottom surface of the substrate 10 and then plating the film 20l′ with a secondary metallic material 20l″. Preferably, the upper conductive layer 20u and the primary metallic film 20l′ are of the same materials. In the illustrated embodiment, the upper conductive layer 20u and the primary metallic film 20l′ are of copper (Cu), and the secondary metallic material 20l″ is of gold (Au), a nickel/gold (Ni/Au) or the like.

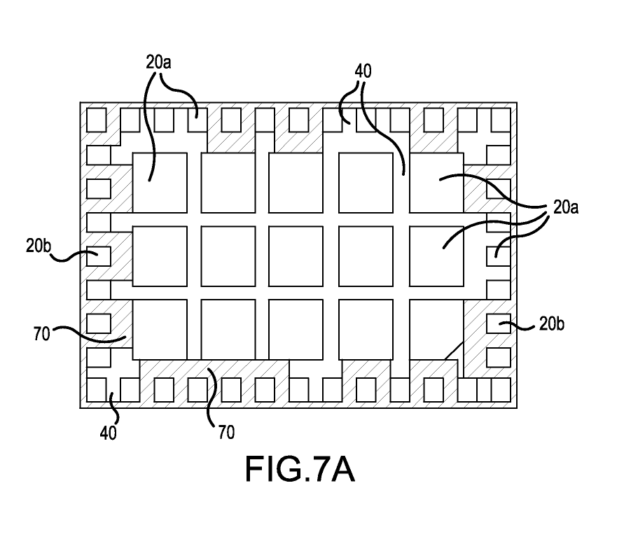

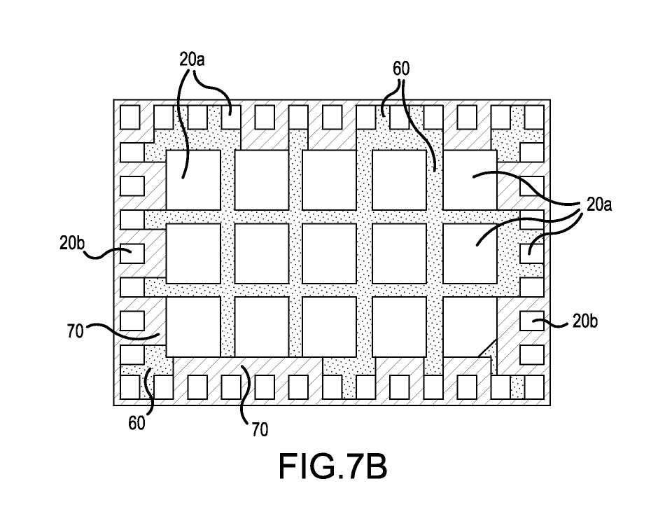

Then the conductive layers 20u, 20l are selectively etched by one or more processes, conventional per se, to form the conductive pads 20. In this respect, the selective etching of the lower conductive layer 20l includes etching through the secondary metallic material 20l″ of Au or Ni/Au and is controlled to leave exposed regions of the primary metallic film 20l′ of copper (Cu) between select ones of the resulting pads for reasons that will be described later on in more detail with reference to FIGS. 7A and 7B. These regions of Cu are thinner (by 5-6 μm, for example) than the regions constituted by the Cu and the Au or Ni/Au plating. Thus, pads (or lands) 20 formed at the top of the substrate 10 may be Cu pads (or lands) and pads (or lands) 20 formed at the bottom of the substrate 10 may be Cu pads provided with Au or Ni/Au contacts.

The vias 30 are formed by a process that is also conventional, per se. In this respect, when the vias are through-vias, for example, the vias 30 may be formed before the conductive layers 20u, 20l are formed by drilling holes (via holes) through the substrate 10 and plugging or coating the holes with electrically conductive material. Furthermore, although not shown, the base 100 may be formed in a batch process in which the conductive layers 20u and 20l are formed on top and bottom surfaces of a panel, and the panel is routed or otherwise cut into sections each constituted by one substrate 10 as shown in FIG. 2.

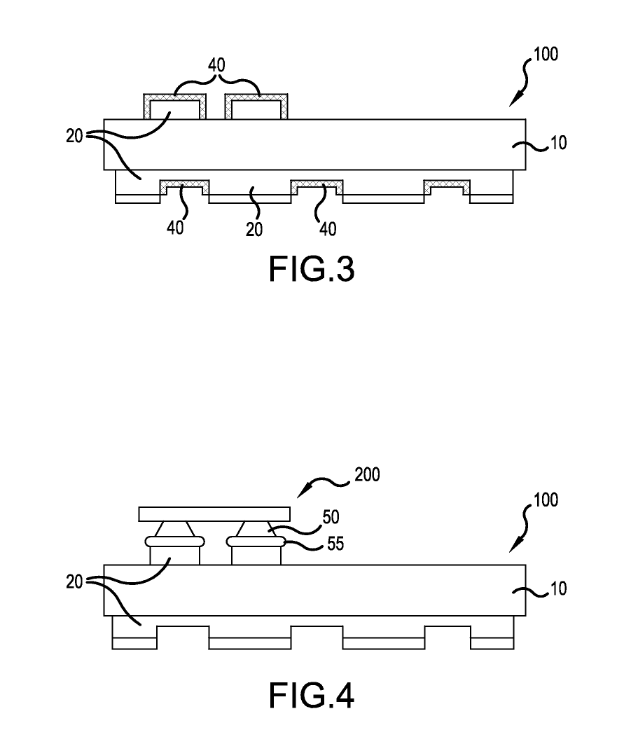

The method of FIG. 1 will now be described in more detail with reference to FIGS. 3-6. Note, in these figures the base 100 is shown in a simplified form for the sake of clarity. In particular, only the substrate 10 and certain ones of the pads 20 of the base 100 are shown.

Referring to FIGS. 1 and 3, OSP surface finish process S1 is carried out for the purpose of coating the pads 20 at the top surface of the substrate with organic solderablity preservative (OSP). For example, the base 100 is immersed in a bath of the organic solderability preservative (OSP). The OSP is a water-based organic compound that selectively bonds to copper. As a result, a coating 40 of the organic solderability preservative (OSP) is formed on the exposed Cu pads 20 at the top of the substrate 10 and on the exposed regions of Cu extending between the pads 20 at the bottom surface of the substrate 100.

Referring to FIGS. 1 and 4, next, in the assembly process S2, an electronic component(s) 200 is disposed on the base 100 and electrically connected to respective ones of the pads 20 at the top of the substrate of the base. Each electronic component 200 may be an SMT component (a chip or die that can be surface mounted to the conductive pads 20) or an FC component (a chip or die that can be flip chip mounted to the conductive pads 20). Thus, the electronic module may be a semiconductor device package.

In the illustrated example, the electronic component 200 is a chip or die having tin-plated Cu pillars 50. The pillars 50 are soldered to pads 20, respectively, thereby electrically connecting (the IC of) the component 200 to the base 100 and, in particular, to the pads 20 at the bottom of the base through the pads 20 at the top of the base and the through vias (30 in FIG. 2). To this end, flux is applied so as to be interposed between the pillars 50 and the pads 20 when the pillars 50 of the electronic component 200 are set on the pads, and the resultant structure is baked. The tin reflows, as represented by reference numeral 55, and thereby physically and electrically connects the component 200 to the pads 20.

At this time, i.e., during the soldering process, the coating 40 of OSP protects the copper of the pads 20. However, the heat of the bake process causes the coating 40 of the OSP on the pads 20 to undergo an exchange process with the flux, wherein the OSP that has been protecting the pads 20 evacuates. On the other, hand, and although not shown, the OSP may remain on the regions of Cu that were exposed at the bottom of the substrate 10. That is, after the assembly process S2 has been performed remnants of the coating 40 of OSP may exist on regions between pads 20 at the bottom of the substrate 10.

Referring to FIGS. 1 and 5, next, in the overmold process S3, the electronic component(s) is/are covered with a molding compound 300. To this end, the structure shown in FIG. 4 may be placed in a mold, and the compound in liquid or semi-solid form is injected into the mold. Then the compound is cured, which may include a baking process. As a result, the molding compound 300 is molded to the substrate 10. At this time, and again, although not shown, remnants of the OSP may exist on the copper (Cu) that had been exposed at the bottom of the substrate 10. Also, it should be noted that the compound 300 is selected or formulated so as to be resistant to chemicals used in the subsequent oxide surface finish process S4.

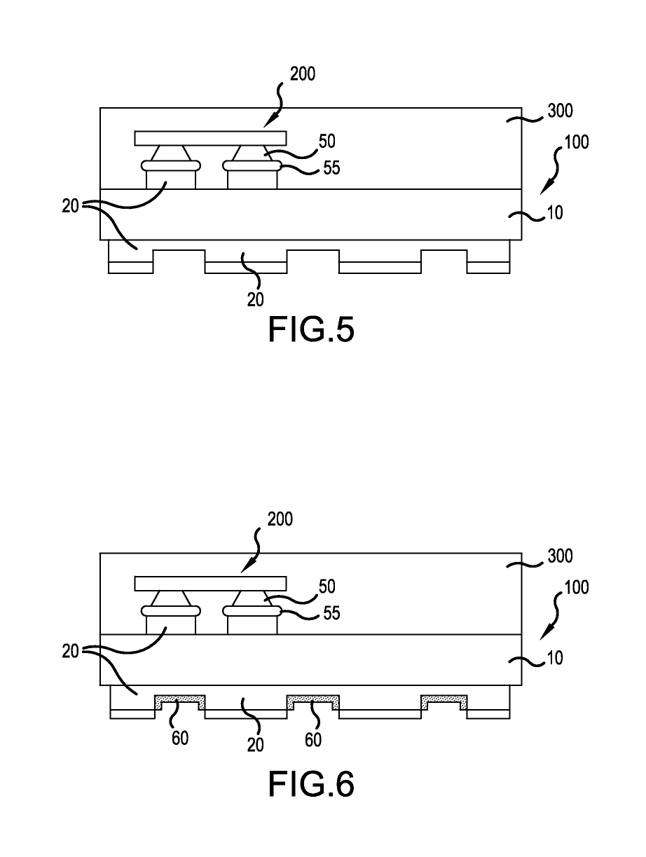

Referring to FIGS. 1 and 6, the oxide surface finish process S4 is performed to form a solder resist 60 at regions between respective ones of the pads 20 at the bottom surface of the substrate. The term “resist” will refer to the fact that the surface finish produced by process S4 is substantially non-wettable by solder. To this end, the oxidation process forms an organo-metallic layer as the solder resist 60 at the exposed regions of copper (Cu) at the bottom surface of the substrate. In an example of the illustrated embodiment, the organo-metallic layer is a film comprising benzotriazole (BTA: C₆H₅N₃) and copper (Cu). A working example of the thickness of the BTA film in this embodiment is 15 nm. Applicant has found that an organo-metallic film comprising BTA is particularly non-wettable by solder, i.e., is especially effective as the solder resist 60. The solder resist 60 may be formed by immersing the structure shown in FIG. 5 in a bath comprising a solution that reacts with the copper (Cu) between the pads 20 at the bottom surface of the substrate 10 to produce the organo-metallic compound. At this time, the plating (Au or Ni/Au, for example) prevents the solution from reacting with the surface of the pads 20 at the bottom of the substrate 10 and the molding compound 300 protects the electronic component(s) 200 and the pads 20 at the top surface of the substrate 10. A suitable solution for use in the oxide surface finish process S4 is Bondfilm® solution produced by Atotech USA, Inc.

In this respect, and for purposes of illustration, an example of a reaction that produces an organo-metallic compound with copper (Cu) is:

2Cu+H₂SO₄+H₂O₂+n[A]+n[B]→CuSO₄+2H₂O+Cu[A+B]n

FIGS. 7A and 7B show the bottom of a module as the module is fabricated by a method according to the present inventive concept.

More specifically, FIG. 7A shows the bottom of the base after the OSP surface finish process S1 (FIG. 1) has been completed. At this time, as described above, the OSP 40 adheres to only regions of exposed copper (Cu).

As can be appreciated from the figure, therefore, in this embodiment, the exposed regions of the primary metallic film of copper (corresponding to 20l′ in FIG. 2) are left between only select ones of the pads (20a) at the bottom of the substrate (with these pads 20a including some of the larger central pads and some of the smaller peripheral pads in the illustrated example). These pads 20a are to have a common potential such as a ground potential and thus may be referred to as “common-net pads 20a”. That is, common-net pads 20a in this example may form a common ground plane for the module. On the other hand, other ones of the pads at the bottom surface of the substrate, namely pads 20b in the figure, are electrically isolated from the others of the pads 20a and 20b at the bottom of the base. In this example, the pads 20b include only respective ones of the smaller peripheral pads and are pads through which electromagnetic signals (e.g., RF signals) are transmitted. Furthermore, reference numeral 70 designates the regions of isolation between the pads 20b and adjacent ones of the pads. In this example, the regions of isolation 70 may be provided by a layer of dielectric forming the bottom surface of the substrate. Such a dielectric layer can be formed on the bottom of an insulating layer of the substrate as part of the process, corresponding to that shown in FIG. 2, of providing the base 100.

On the other hand, FIG. 7B shows the solder resist 60 extending between the common-net pads 20a at the bottom surface of the substrate at the completion of the oxide surface finish process S4 (FIG. 1). As can be appreciated from this figure, OSP 40 at the bottom of the substrate has been evacuated by the assembly process S2 (FIG. 1), thereby again exposing regions of copper (Cu) between pads 20a; then the oxide surface finish process S4 forms the organo-metallic compound (comprising BTA) as solder resist 60 at the surface of the exposed copper (Cu). Therefore, when the module is soldered to a PCB, the solder will not span or otherwise bridge adjacent ones of the pads 20, including the common-net pads 20a, during the reflow process. Notably, the bondfilm chemistries will strip any existing OSP or other contaminants leaving a substantially pure surface of copper before the oxide is applied.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments and examples described above but by the following claims.

1. A method of manufacturing an electronic module, the method comprising:
providing a base including a substrate having top and bottom surfaces, the substrate comprising an electrically insulating material, and conductive pads at each of the top and the bottom surfaces of the substrate;
coating the pads at the top surface of the substrate with organic solderability preservative (OSP);
disposing at least one electronic component on the base and electrically connecting the at least one electronic component to respective ones of the pads at the top of the substrate of the base;
covering the at least one electronic component with a molding compound; and
forming a solder resist at regions between respective ones of the pads at the bottom surface of the substrate, wherein the forming of the solder resist comprises an oxidation process.

2. The method as claimed in claim 1, wherein the connecting of the at least one electronic component comprises soldering the at least one electronic component to respective ones of the pads at the top of the substrate.

3. The method as claimed in claim 1, wherein the providing of the base comprises forming a conductive layer comprising a film of metal on the bottom of the substrate, and selectively etching the conductive layer to form an array of conductive pads and leave exposed regions of the metal between said respective ones of the pads.

4. (canceled)

5. A method of manufacturing an electronic module, the method comprising:
providing a base including a substrate having top and bottom surfaces, the substrate comprising an electrically insulating material, exposed copper (Cu) pads at the top surface of the substrate, and a conductive layer comprising a film of copper (Cu) at the bottom surface of the substrate,
wherein the conductive layer has a first portion constituting an array of conductive lands, and a second portion of exposed copper (Cu), the second portion extending between respective ones of the lands at the bottom surface of the substrate and being thinner than the first portion;
a metal surface finishing process comprising coating the exposed Cu pads at the top surface of the substrate with organic solderability preservative (OSP);
disposing at least one electronic component on the top surface of the substrate and soldering the at least one electronic component to the pads at the top surface of the substrate;
covering the at least one electronic component with a molding compound; and
producing a solder resist comprising an organo-metallic compound at the surface of the portion of exposed copper (Cu) at the bottom surface of the substrate.

6. The method as claimed in claim 5, wherein the providing of the base comprises forming a conductive layer comprising a film of copper (Cu) on the bottom of the substrate, and selectively etching the conductive layer to form the array of conductive lands and to leave regions of the film of copper (Cu) exposed between said respective ones of the lands.

7. The method as claimed in claim 6, wherein the producing of the solder resist comprises forming a film of benzotriazole (BTA) at the surface of the regions of copper (Cu) exposed at the bottom surface of the substrate.

8. The method as claimed in claim 6, wherein the providing of the base comprises forming a conductive layer comprising a film of copper (Cu) on the bottom of the substrate, plating the film of copper (Cu), and selectively etching the conductive layer to form the array of conductive lands and to leave regions of the film of copper (Cu) exposed between said respective ones of the lands, each of the conductive lands comprising a pad of plated Cu.

9. The method as claimed in claim 8, wherein the oxidation process forms a film of benzotriazole (BTA) as the solder resist.

10. The method as claimed in claim 8, wherein the plating comprises plating the film of copper (Cu) with gold (Au) or with nickel (Ni) and gold (Au).

11. The method as claimed in claim 8, wherein the producing of the solder resist comprises immersing a structure comprising the base, and the at least one electronic component covered by the molding compound into a bath comprising a solution that reacts with the copper (Cu) exposed at the bottom surface of the substrate to form an organo-metallic compound as the solder resist.

12. The method as claimed in claim 8, wherein the metal surface finishing process comprises immersing the base in a bath of the organic solderability preservative (OSP) such that the exposed Cu at the top and bottom surface of the substrate becomes coated with organic solderability preservative (OSP).

13. The method as claimed in claim 12, wherein the producing of the solder resist comprises immersing a structure comprising the base, and the at least one electronic component covered by the molding compound into a bath comprising a solution that reacts with the copper (Cu) exposed at the bottom surface of the substrate to form an organo-metallic compound as the solder resist.

14. The method as claimed in claim 5, wherein the metal surface finishing process comprises immersing the base in a bath of the organic solderability preservative (OSP) such that the exposed copper (Cu) at the top and bottom surface of the substrate becomes coated with organic solderability preservative (OSP).

15. The method as claimed in claim 14, wherein the producing of the solder resist comprises immersing a structure comprising the base, and the at least one electronic compound covered by the molding compound into a bath comprising a solution that reacts with the copper (Cu) exposed at the bottom surface of the substrate to form an organo-metallic compound as the solder resist.

16. An electronic module, comprising:
a substrate having top and bottom surfaces, the substrate comprising an electrically insulating material;
conductive pads disposed over each of the top and bottom surfaces of the substrate;
at least one electronic component disposed over the top surface of the substrate and electrically connected to the pads at the top surface of the substrate;
a molding compound covering the at least one electronic component; and
a solder resist comprising an organo-metallic compound at regions between respective ones of the pads at the bottom surface of the substrate.

17. The module as claimed in claim 16, wherein the conductive pads comprise copper (Cu).

18. The module as claimed in claim 17, wherein the pads at the bottom surface of the substrate comprise copper (Cu) plated with gold (Au) or with nickel (Ni) and gold (Au).

19. The module as claimed in claim 17, wherein the organo-metallic compound comprises benzotriazole (BTA).

20. The module as claimed in claim 16, wherein the at least one electronic component is soldered to the pads at the top surface of the substrate.
